(19) United States
(12) Patent Application Publication
(10) Pub. No.: US 2008/0164942 A1
(43) Pub. Date: Jul. 10, 2008

(54) Audio data processing apparatus, terminal, and method of audio data processing

(75) Inventors: Hirokazu Takeuchi, Tokyo (JP); Masataka Osada, Kawasaki-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: KABUSHIKI KAISHA TOSHIBA, Tokyo (JP)

(21) Appl. No.: 11/807,709

(22) Filed: May 30, 2007

(30) Foreign Application Priority Data
Jan. 9, 2007 (JP) P2007-001708

(51) Int. Cl. H03F 1/26

(52) U.S. Cl. 330/149

(57) ABSTRACT

According to an aspect of the invention, there is provided an audio data processing apparatus including: a decoding unit configured to extract an encoding parameter from encoded audio data by decoding the encoded audio data; an acquisition unit configured to acquire a background noise signal; a correction gain calculating unit configured to calculate a correction gain for correcting frequency characteristics of the audio data by using the encoding parameter and the background noise signal; and a frequency characteristics correcting unit configured to correct the frequency characteristics of the audio data based on the correction gain.

### CROSS-REFERENCE TO RELATED APPLICATIONS

This application is based on and claims the benefit of priority from the prior Japanese Patent Application No. 2007-001708, filed on Jan. 9, 2007; the entire contents of which are incorporated herein by reference

### BACKGROUND

1. Technical Field

The present invention relates to audio data processing apparatus, a terminal and a method of audio data processing.

2. Description of Related Art

A background noise canceling technique is generally known in a mobile phone realm. For example, JP-2004-289614 discloses a technique for improving clearness of voice signal where the voice signal is emphasized based on estimated signal characteristic of background noise and signal characteristic of voice signal from a microphone.

### SUMMARY

According to an aspect of the invention, there is provided an audio data processing apparatus including: a decoding unit configured to extract an encoding parameter from encoded audio data by decoding the encoded audio data; an acquisition unit configured to acquire a background noise signal; a correction gain calculating unit configured to calculate a correction gain for correcting frequency characteristics of the audio data by using the encoding parameter and the background noise signal; and a frequency characteristics correcting unit configured to correct the frequency characteristics of the audio data based on the correction gain.

### BRIEF DESCRIPTION OF THE DRAWINGS

In the accompanying drawings:

FIG. 1 is an exemplary block diagram illustrating audio data processing apparatus according to an embodiment of the present invention;

FIG. 2 is an exemplary block diagram illustrating a correction gain calculating unit; and

FIG. 3 is an exemplary graph indicating gain correction.

### DESCRIPTION OF THE EMBODIMENTS

An embodiment of the present invention will be described below with reference to the accompanying drawings.

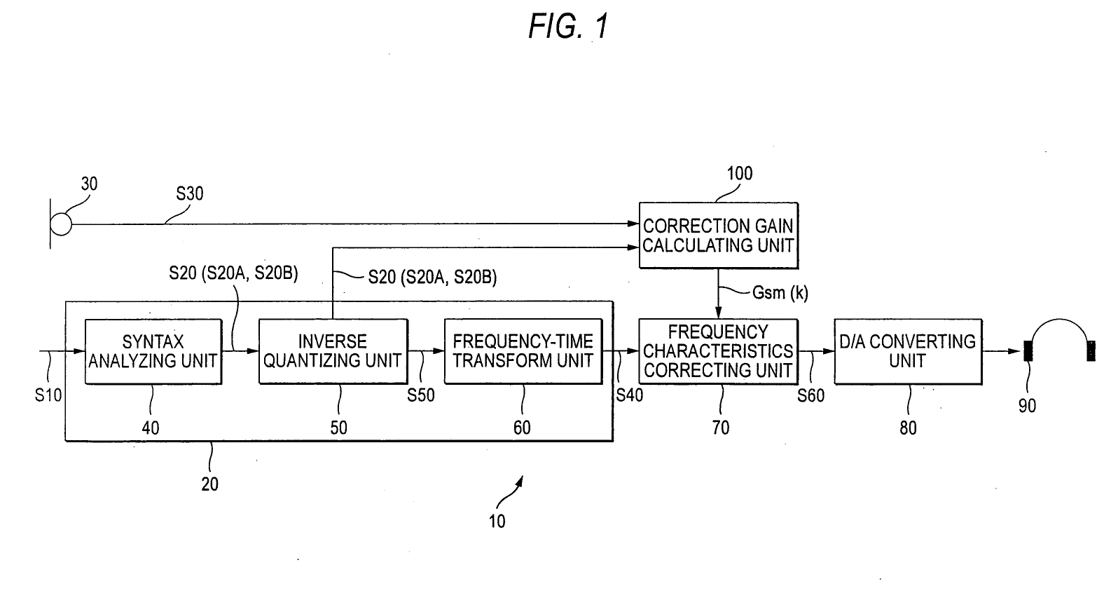

FIG. 1 exemplary shows a constitution of Audio data processing apparatus 10 according to one embodiment of the present invention. The Audio data processing apparatus 10 is usually built in an audio player with a microphone such as a mobile phone. The Audio data processing apparatus 10 has an audio decoder 20 for generating a playback signal S40, which is original audio data before correcting, by decoding encoded audio data S10.

Then, the Audio data processing apparatus 10 corrects frequency characteristics of the playback signal S40 based on an encoding parameter S20 outputted from the audio decoder 20 and a background noise signal S30 obtained by a microphone 30. Thus, influence of a background noise can be reduced even in listening to music, watching a broadcast, etc., in addition to voice communication, etc.

More specifically, in the Audio data processing apparatus 10, the encoded audio data S10, which is read from storage media (not shown) or received by an antenna (not shown), is inputted into a syntax analyzing unit 40. The syntax analyzing unit 40 as parsing means extracts and outputs the audio encoding parameter S20 to an inverse quantizing unit 50 by decoding the encoded audio data S10 with use of, for example, Huffman decoding. The encoding parameter S20 includes a quantization step size S20A called scale factor, and a quantized spectrum S20B composed of a plurality of quantization values which is extracted by quantizing spectrum with the quantization step size S20A. In addition, the quantized spectrum S20B includes quantized audio data in the frequency domain.

Moreover, generally, in an audio encoding method such as AAC (Advanced Audio Coding), redundancy of a spectrum (audio data) transformed into a frequency domain is reduced.

In an audio encoder (not shown), the quantization step size S20A and the quantized spectrum S20B are controlled so as to be quantization noise power having a level, in which no noise is perceived (that is, the noise is masked), for each of frequency bands (scale factor bands) which has frequency resolution based on a human auditory system, in consideration of, for example, signal characteristics such as a tonality (characteristics which indicate a predictability signal in the time domain), and masking characteristics of the hearing (characteristics that a certain signal component auditorily masks signal component which are positioned in the vicinity of the signal in the time domain and the frequency domain).

The inverse quantizing unit 50 inversely quantizes the quantized spectrum S20B based on the quantization step size S20A to convert the quantized spectrum S20B into a spectrum S50 having a normal scale (audio data in a frequency domain).

A frequency-time transforming unit 60 transforms the spectrum S50 in the frequency domain to a PCM (Pulse Code Modulation) signal s40 in the time domain. The playback signal (PCM) S40 is transmitted to a digital-analog (D/A) converting unit 80 via a frequency characteristics correcting unit 70 to be converted into an analog signal (audio signal), and then outputted from a headphones 90 as outputting means.

On the other hand, in the embodiment, the Audio data processing apparatus 10 corrects the frequency characteristics of the playback signal S40 so as to comfortably listen to voice, music and the like, even under presence of background noise. More specifically, in the Audio data processing apparatus 10, the background noise is obtained by the microphone 30 for voice communication to be inputted into a correction gain calculating unit 100 as a background noise signal S30.

The correction gain calculating unit 100 estimates acceptable quantization noise power, which is acceptable quantization noise power, by using the quantization step size S20A and the quantized spectrum S20B transmitted from the syntax analyzing unit 40 via the inverse quantizing unit 50, and calculates the correction gain in a frequency band to be corrected so that power of the background noise signal S30 obtained by the microphone 30 becomes smaller than the acceptable quantization noise power.

First, the frequency characteristics correcting unit 70 subjects the playback signal S40 outputted from the frequency-time converting unit 60 to time-frequency conversion to generate the spectrum which is the audio data in the frequency domain, and then performs equalizing processing, which is correcting processing of the frequency characteristics by multiplying the spectrum by a correction gain Gsm(k) calculated by the correction gain calculating unit 100.

Next, the frequency characteristics correcting unit 70 subjects the spectrum subjected to the correcting processing to the frequency-time conversion to generate a playback signal S60 subjected to the correcting processing of the frequency characteristics, and then the playback signal S60 is converted into an analog signal in the D/A converting unit 80 and the analog signal is playbacked from the headphones 90. Thus, the influence of the background noise is reduced, and sound quality can be improved.

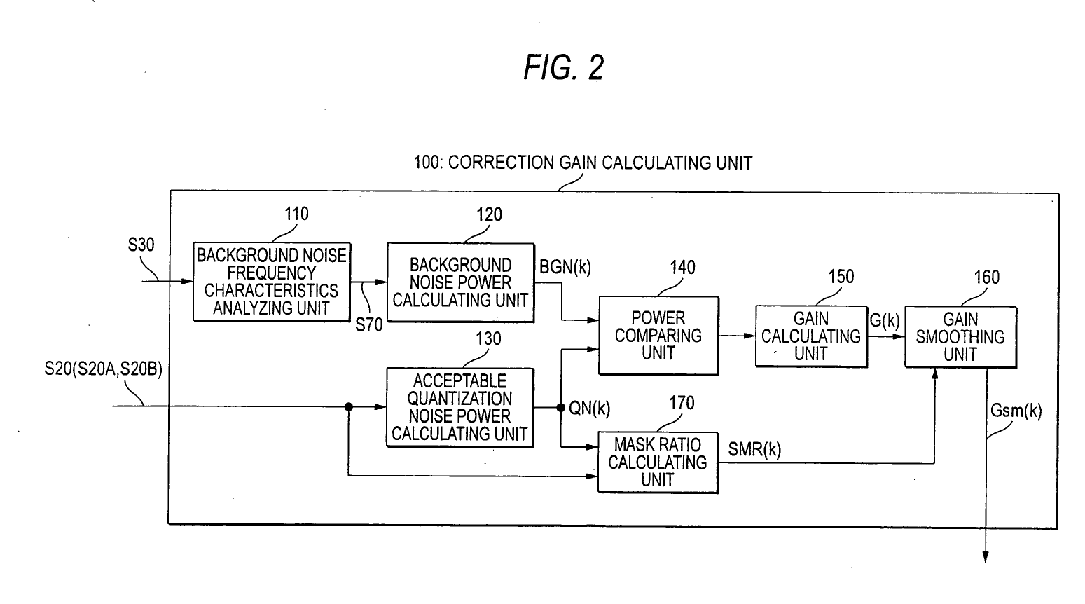

FIG. 2 shows a constitution of the correction gain calculating unit 100. In the correction gain calculating unit 100, the background noise signal S30 inputted from the microphone 30 is first inputted into a background noise frequency characteristics analyzing unit 110. The background noise frequency characteristics analyzing unit 110 transforms the background noise signal S30 in the time domain into a background noise spectrum S70 in the frequency domain.

A background noise power calculating unit 120 calculates background noise power for each frequency band (scale factor band), that is the same as frequency band for inverse quantization, from the background noise spectrum S70, and then corrects the background noise power based on coefficients, which are calculated beforehand in consideration of analog characteristics of the microphone 30 and an attenuation rate of the background noise which is leaked into the headphones 90, to calculate background noise power BGN(k). Moreover, k represents an index of each frequency band.

On the other hand, an acceptable quantization noise power calculating unit 130 calculates acceptable quantization noise power QN(k) by using the quantization step size S20A and quantized spectrum S20B outputted from the inverse quantizing unit 50 of the audio decoder 20.

More specifically, in the case where the audio encoding method is, for example, AAC, the inverse-quantization processing in the inverse quantizing unit 50 is represented by the following equation (1):

$$invq ( i ) = {q ( i )}^{\frac{4}{3}} \cdot {2}^{\frac{sf ( k ) - 100}{4}} \qquad ( 1 )$$

wherein k represents the index of the frequency band (scale factor band), sf(k) represents the quantization step size (scale factor), i represents a frequency index in the frequency band, q(i) represents the quantization value (quantized spectrum coefficient (integer)), and invq(i) represents an inverse-quantized value.

When the inverse-quantization value invq(i) of equation (1) is represented as a function of k and q(i), IQ(k, q(i)), a quantization step size Qstep(k, i) corresponding to the quantization value q(i) is represented by the following equation (2)

Qstep(k,i)=IQ(k,q(i)+0.5)−IQ(k,q(i)−0.5) (2)

The quantization noise power QN(k) in the frequency band k is calculated by the following equation (3):

$$QN ( k ) = \frac{{\sum }_{i = sfb 0 ( k )}^{sfb 1 ( k )} Q {step ( k , i )}^{2}}{12} \qquad ( 3 )$$

wherein sfb0(k) represents a low band end of the frequency index in the frequency band (scale factor band) k, and sfb1(k) represents a high band end of the frequency index in the frequency band k.

Generally, in consideration of a signal level of an input signal and masking characteristics of human auditory system, the audio encoder calculates a masking threshold as a noise level, in which no quantization noise is perceived, and controls the quantization step size in accordance with the masking threshold.

Accordingly, when the noise power is smaller than the quantization noise power QN(k), no noise is perceived and the noise power is allowed. Thus, the allowable quantization noise power calculating unit 130 outputs this quantization noise power QN(k) as the allowable quantization noise power QN(k) in the frequency band k.

A power comparing unit 140 compares the background noise power BGN(k) with the acceptable quantization noise power QN(k) for all the frequency bands and outputs the index k of the frequency band to be corrected, in which the background noise power BGN(k) is larger than the allowable quantization noise power QN(k), and the background noise power BGN(k) and the acceptable quantization noise power QN(k) to a gain calculating unit 150.

The gain calculating unit 150 calculates and outputs a correction gain G(k) (>1.0) for raising the signal level in the frequency band to be corrected to a gain smoothing unit 160 by using the following equation (4) so that the background noise power BGN(k) becomes smaller than the acceptable quantization noise power QN(k).

$$G ( k ) = \frac{BGN ( k )}{QN ( k )} \qquad ( 4 )$$

The gain smoothing unit 160 subjects the correction gain G(k) to smoothing processing and outputs the smoothed correction gain to the frequency characteristics correcting unit 70. Thus, discontinuity of characteristics of the vicinity of the corrected frequency bands or a excessive difference between the corrected signal and the original signal can be attenuated which is caused by gain correction of only a specific frequency band.

The gain smoothing unit 160 calculates correction gains Gs(k) in the vicinity of frequency band by using the following equation (5) in the case where the background noise power BGN(k) is larger than the allowable quantization noise power QN(k).

Gs(k)=α(k₀,k−k₀)·G(k₀) (5)

wherein k0 represents the frequency band to be corrected, and α represents smoothing coefficients. Here, the smoothing coefficient α are positive constant coefficients for each frequency band, and has a convex shape in which α (k₀, 0) indicating k=k₀ is a peak, and the coefficient simply increases before the peak and simply decreases after the peak.

On the other hand, a mask ratio calculating unit 170 (power ratio calculating unit) calculates, in consideration of the masking characteristics of human auditory system, a mask ratio SMR(k), which is a power ratio of the inverse-quantized spectrum S20 to the acceptable quantization noise power QN(k) in the frequency band k to be corrected, by using the acceptable quantization noise power QN(k), and the quantization step size S20A and quantized spectrum S20B.

More specifically, the mask ratio calculating unit 170 calculates and outputs the mask ratio SMR(k) in the frequency band k to the gain smoothing unit 160 by using the following equation (6) using the acceptable quantization noise power QN(k) and the inverse-quantization value invq(i).

$$SMR ( k ) = \frac{{\sum }_{i = sfb 0 ( k )}^{sfb 1 ( k )} {invq ( i )}^{2}}{QN ( k )} \qquad ( 6 )$$

The gain smoothing unit 160 corrects the smoothing coefficient α in the frequency domain in accordance with the mask ratio SMR(k). More specifically, the gain smoothing unit 160 compares the mask ratio SMR(k) with a predetermined threshold. The smoothing coefficient α is corrected so as to be small (steep inclination) in the case that the mask ratio SMR(k) is larger than the threshold. Moreover, in this case, if a plurality of thresholds are provided, the smoothing coefficient α may be corrected by a plurality of stages.

A smoothing coefficient α_{SMR} (k₀, k) obtained by the correction is represented by the following equation (7) in which correction of the smoothing coefficient α is represented by a function F( ).

α_{SMR}(k₀,k)=α(k₀,k−k₀)·F(SMR(k₀)) (7)

Accordingly, since a frequency band having a large mask ratio SMR generally has a strong tonality (weak noise property) and has a little influence on the vicinity of frequency band, the smoothing coefficient α (k, i≅0) of the vicinity of frequency band is corrected so as to be small (so that inclinations of simple increase and decrease are steep).

On the other hand, since a frequency band having a small mask ratio SMR generally has a weak tonality (strong noise property) and has a lot of influence on the vicinity of the frequency band, the smoothing coefficient α (k, i≅0) of the vicinity of frequency band is corrected so as to hardly become small (so that the inclinations are prevented from being steep).

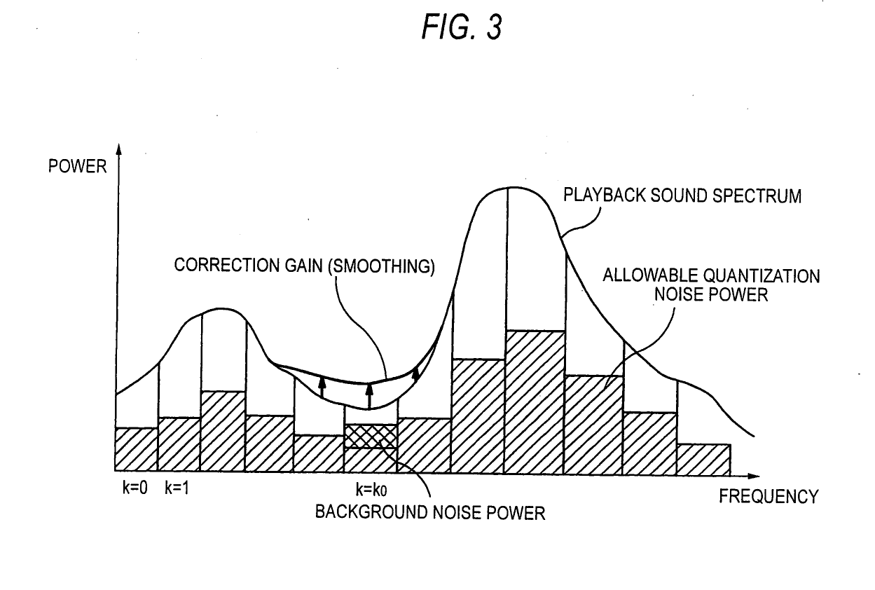

FIG. 3 indicates gain correction. When the power comparing unit 140 decides that the background noise power BGN(k) is larger than the acceptable quantization noise power QN(k) in the frequency band k₀, the gain calculating unit 150 calculates the correction gain G(k) so that the background noise power BGN(k) becomes smaller than the acceptable quantization noise power QN(k). Then, the gain smoothing unit 160 performs the smoothing processing based on the gain Gs(k) in the vicinity of frequency band to be corrected to calculate the correction gain G(k). In this case, the gain smoothing unit 160 may perform the smoothing processing for a time domain after performing smoothing in the frequency domain, and thus an uncomfortable noise caused by discontinuity of the playback signals can be suppressed.

The gain smoothing unit 160 calculates final correction gains Gsm(k) for all the frequency bands by using the following equation (8), while thus considering the mask ratio SMR(k) transmitted from the mask ratio calculating unit 170.

$${G}_{SM} ( k ) = {\sum }_{{k}_{0} = {min\_k}_{0}}^{{max\_k}_{0}} {α}_{SMR} ( {k}_{0} , k ) \cdot G ( {k}_{0} ) , \qquad ( 8 )$$

wherein min_k₀ represents the low band end of the index of the frequency band to be corrected, and max_k₀ represents the high band end of the index of the frequency band to be corrected. Addition is performed for only a inside frequency band among the frequency bands to be corrected.

According to the embodiment, the influence of the background noise is reduced and the sound quality can be improved in not only playing back voice but playing back the encoded audio data S10 such as music. Additionally, in analyzing the signal characteristics of the acceptable quantization noise power QN(k) and the like, an analyzing time is shortened and high speed processing can be realized by using the encoding parameter S20.

Moreover, the present invention is not limited to the above embodiment. For example, the correction gain G(k) is transmitted from the gain calculating unit 150 of the correction gain calculating unit 100 to the frequency characteristics correcting unit 70, and thus the frequency characteristics correcting unit 70 may correct the frequency characteristics by using the correction gain G(k).

According to the above-described embodiment, the quality of playbacked audio signal can be improved regardless of the kind of inputted audio encoded data.

What is claimed is:

1. An Audio data processing apparatus comprising:
a decoding unit configured to extract an encoding parameter from encoded audio data by decoding the encoded audio data;
an acquisition unit configured to acquire a background noise signal;
a correction gain calculating unit configured to calculate a correction gain for correcting frequency characteristics of the audio data by using the encoding parameter and the background noise signal; and
a frequency characteristics correcting unit configured to correct the frequency characteristics of the audio data based on the correction gain.

2. The Audio data processing apparatus according to claim 1, wherein the correction gain calculating unit includes:
an acceptable quantization noise power calculating unit configured to calculate acceptable quantization noise power for each frequency band by using a quantization step size and a quantization spectrum contained in the encoding parameter;
a background noise frequency characteristics analyzing unit configured to analyze a frequency characteristic of the background noise signal;
a background noise power calculating unit configured to calculate a background noise power for each frequency band by using an analysis result obtained by the background noise frequency characteristics analyzing unit;
a power comparing unit configured to compare the acceptable quantization noise power and the background noise power for each frequency band; and
a gain calculating unit configured to calculate the correction gain for raising a signal level of the audio data in a frequency band to be corrected in which the background noise power is determined to be larger than the acceptable quantization noise power.

3. The Audio data processing apparatus according to claim 2, wherein the correction gain calculating unit includes:
a power ratio calculating unit configured to calculate a power ratio of the quantization spectrum to the acceptable quantization noise power in the frequency band to be corrected by using the quantization step size and the quantization spectrum, and the acceptable quantization noise power; and
a gain smoothing unit configured to modify the correction gain in the vicinity of a frequency band to be corrected in accordance with the power ratio.

4. The Audio data processing apparatus according to claim 1, wherein the decoding unit includes:
an extracting unit configured to extract the encoding parameter including a quantization step size and a quantization spectrum from the encoded audio data;
an inverse quantizing unit configured to inversely quantize the quantization spectrum based on the quantization step size; and
a frequency-time converting unit configured to generate the audio data by subjecting the inversely quantized quantization spectrum to frequency-time transformation.

5. A terminal comprising:
a decoding unit configured to extract an encoding parameter from encoded audio data by decoding the encoded audio data;
an acquisition unit configured to acquire a background noise signal;
a correction gain calculating unit configured to calculate a correction gain for correcting frequency characteristics of the audio data by using the encoding parameter and the background noise signal;
a frequency characteristics correcting unit configured to correct the frequency characteristics of the audio data based on the correction gain;
a digital-analog converting unit configured to generate an audio signal by subjecting the audio data including the corrected frequency characteristics to digital-analog conversion; and
an outputting unit configured to output the audio signal.

6. A method of Audio data processing comprising:
extracting an encoding parameter from encoded audio data by decoding the encoded audio data;
acquiring a background noise signal;
calculating a correction gain for correcting frequency characteristics of the audio data by using the encoding parameter and the background noise signal; and
correcting the frequency characteristics of the audio data based on the correction gain.

7. The method of Audio data processing according to claim 6, comprising:
calculating acceptable quantization noise power for each predetermined frequency band by using a quantization step size and a quantization spectrum contained in the encoding parameter;
analyzing a frequency characteristic of the background noise signal;
calculating a background noise power for each frequency band by using an analysis result obtained by the background noise frequency characteristics analyzing unit;
comparing the acceptable quantization noise power and the background noise power for each frequency band; and
calculating the correction gain for raising a signal level of the audio data in a frequency band to be corrected in which the background noise power is determined to be larger than the acceptable quantization noise power.

8. The method of Audio data processing according to claim 7, comprising:
calculating a power ratio of the quantization spectrum to the acceptable quantization noise power in the frequency band to be corrected by using the quantization step size and the quantization spectrum, and the acceptable quantization noise power; and
modifying the correction gain in the vicinity of a frequency band to be corrected in accordance with the power ratio.

9. The method of Audio data processing according to claim 6, comprising:
extracting the encoding parameter including a quantization step size and a quantization spectrum from the encoded audio data;
quantizing the quantization spectrum inversely based on the quantization step size; and
generating the audio data by subjecting the inversely quantized quantization spectrum to frequency-time transformation.

10. A computer program product for enabling a computer to perform audio data processing, comprising:
a decoding unit configured to extract an encoding parameter from encoded audio data by decoding the encoded audio data;
an acquisition unit configured to acquire a background noise signal;
a correction gain calculating unit configured to calculate a correction gain for correcting frequency characteristics of the audio data by using the encoding parameter and the background noise signal; and
a frequency characteristics correcting unit configured to correct the frequency characteristics of the audio data based on the correction gain.

11. The computer program product according to claim 10, wherein the correction gain calculating unit includes:
an acceptable quantization noise power calculating unit configured to calculate acceptable quantization noise power for each predetermined frequency band by using a quantization step size and a quantization spectrum contained in the encoding parameter;
a background noise frequency characteristics analyzing unit configured to analyze a frequency characteristic of the background noise signal;
a background noise power calculating unit configured to calculate a background noise power for each frequency band by using an analysis result obtained by the background noise frequency characteristics analyzing unit;
a power comparing unit configured to compare the acceptable quantization noise power and the background noise power for each frequency band; and
a gain calculating unit configured to calculate the correction gain for raising a signal level of the audio data in a frequency band to be corrected in which the background noise power is determined to be larger than the acceptable quantization noise power.

12. The computer program product according to claim 11, wherein the correction gain calculating unit includes:
a power ratio calculating unit configured to calculate a power ratio of the quantization spectrum to the acceptable quantization noise power in the frequency band to be corrected by using the quantization step size and the quantization spectrum, and the acceptable quantization noise power; and
a gain smoothing unit configured to modify the correction gain in the vicinity of a frequency band to be corrected in accordance with the power ratio.

13. The computer program product according to claim 10, wherein the decoding unit includes:
an extracting unit configured to extract the encoding parameter including a quantization step size and a quantization spectrum from the encoded audio data;
an inverse quantizing unit configured to inversely quantize the quantization spectrum based on the quantization step size; and
a frequency-time converting unit configured to generate the audio data by subjecting the inversely quantized quantization spectrum to frequency-time transformation.
